(19) United States
(12) Patent Application Publication
(10) Pub. No.: US 2014/0063705 A1
(43) Pub. Date: Mar. 6, 2014

(54) MOBILE COMMUNICATION DEVICE AND MANUFACTURING METHOD THEREOF

(71) Applicant: Pantech Co., Ltd., Seoul (KR)

(72) Inventor: Chang Jin SONG, Seoul (KR)

(73) Assignee: Pantech Co., Ltd., Seoul (KR)

(21) Appl. No.: 14/016,862

(22) Filed: Sep. 3, 2013

(30) Foreign Application Priority Data
Sep. 3, 2012 (KR) 10-2012-0097042

(51) Int. Cl. H05K 5/02; H05K 5/00

(52) U.S. Cl. CPC H05K 5/0217; H05K 5/0017
USPC 361/679.01; 29/428

(57) ABSTRACT

A device includes a display unit, a cover glass to at least partially overlap the display unit, and a housing unit including a stopper portion, the stopper portion extending to overlap a portion of the display unit, and the stopper portion being adjacent to the cover glass.

### CROSS-REFERENCE TO RELATED APPLICATION

This application claims priority to and the benefit under 35 U.S.C. §119(a) of Korean Patent Application No. 10-2012-0097042, filed on Sep. 3, 2012, the entire disclosure of which is incorporated by reference for all purposes.

### BACKGROUND

1. Field

The following disclosure relates to a device and a method for increasing size of a display region of the device.

2. Discussion of the Background

Mobile communication devices may be configured to have a large screen and a full screen in accordance with user demand for a larger screen. However, when the size of the device increases, there is a problem in that it is difficult to increase the size of the display up to the size of the device due, at least in part, to the arrangement or placement of signal lines. In order to solve such a problem, there have been various attempts for decreasing the width of a marginal portion, which refers to an area from an end or edge portion of the display region, on which an image is displayed, to an edge of a housing exterior.

With respect to mobile communication devices in a related art, a display module is mounted in a housing of the mobile communication device, and a touch sensor and a cover glass are arranged thereon. The touch sensor and the cover glass are attached to the housing using an adhesive or an adhesive tape applied to the lower faces of the touch sensor and the cover glass to prevent the display module, the touch sensor, and the cover glass from falling out of the housing.

In the related art, to decrease the size of the mobile communication device, while a distance from an end portion of the display region on which an image is displayed to an edge of of the display module has been available to be decreased, there is a problem in the structure of the display module, which may limit the decrease of the distance. For example, a decrease of 0.2 millimeter (mm) has been achieved, but such decrease is limited.

In addition, the size of an area in which the touch sensor and the cover glass are bonded and fixed to the housing may be available to be decreased. However, when the size of the bonding and fixing area are decreased, the adhesive force between the touch sensor and the cover glass is weakened, and accordingly, a crack may occur in the display module due to the display module and/or the cover glass coming out of its placement upon receiving a shock thereto. In addition, when the size of the bonding and fixing area decreases, a foreign material may flow in, and accordingly, it may be difficult to decrease the size of the bonding and fixing area even when the adhesive force is increased by using a high-strength adhesive tape.

In addition, the thickness of the housing may be considered to be decreased. However, a minimum thickness of the housing that is required for securing the rigidity and the durability of the mobile communication device needs to be assured. Further, the thickness of the side face of the housing changes depending on the design thereof, such as when the side face of the housing is configured to be round. Accordingly, it may be difficult to decrease the thickness of the housing in terms of the structure and the design as well.

As described above, various attempts have been made to reduce the size of the mobile communication device with a screen of the display region being secured while maintaining durability and the stability of the mobile communication device.

### SUMMARY

Exemplary embodiments of the present invention provide a device and a method for increasing size of a display region of the device.

Additional features of the invention will be set forth in the description which follows, and in part will be apparent from the description, or may be learned by practice of the invention.

Exemplary embodiments of the present invention provide a device including a display unit, a cover glass to at least partially overlap the display unit, and a housing unit including a stopper portion, the stopper portion extending to overlap a portion of the display unit, and the stopper portion being adjacent to the cover glass.

Exemplary embodiments of the present invention provide a device including a display unit, a cover glass to overlap a first portion of the display unit, the first portion being less than an entire portion of the display unit, and a housing unit including a stopper portion, the stopper portion to overlap a second portion of the display unit.

Exemplary embodiments of the present invention provide a method for manufacturing a device including preparing a display unit, mounting the display unit and a cover glass to a housing unit including a stopper portion, in which the cover glass at least partially overlaps the display unit, and the stopper portion extends to overlap a portion of the display unit.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view of a mobile communication device according to an exemplary embodiment of the present invention.

FIG. 2 is a partial enlarged view of a mobile communication device according to an exemplary embodiment of the present invention.

FIG. 3 is a partial enlarged view of a mobile communication device according to an exemplary embodiment of the present invention.

FIG. 4 is a partial enlarged view of a mobile communication device according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. It will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ). Throughout the drawings and the detailed description, unless otherwise described, the same drawing reference numerals are understood to refer to the same elements, features, and structures. The relative size and depiction of these elements may be exaggerated for clarity.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Although some features may be described with respect to individual exemplary embodiments, aspects need not be limited thereto such that features from one or more exemplary embodiments may be combinable with other features from one or more exemplary embodiments.

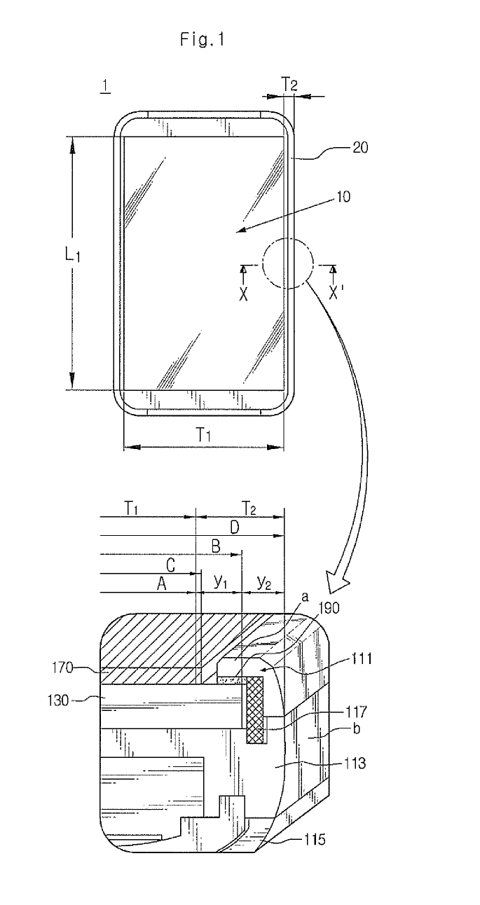

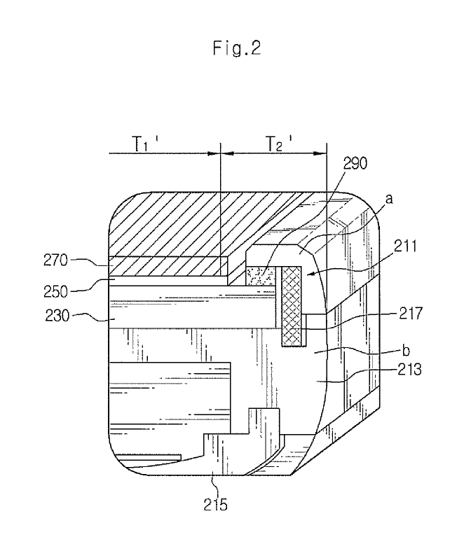

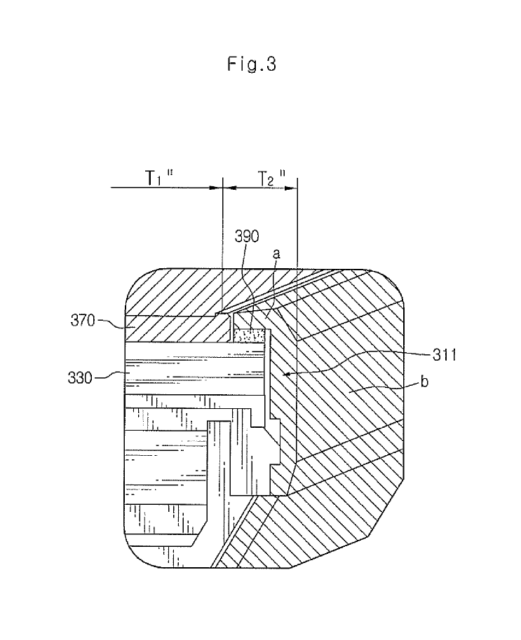

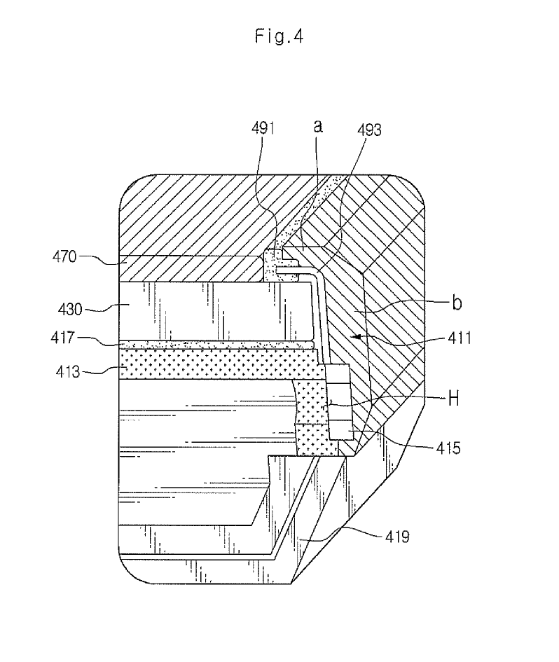

Hereinafter, a device and a method for manufacturing thereof according to exemplary embodiments of the present invention will be disclosed in more detail with reference to FIG. 1, FIG. 2, FIG. 3, and FIG. 4.

FIG. 1 is a plan view of a mobile communication device according to an exemplary embodiment of the present invention.

As illustrated in FIG. 1, a mobile communication device 1 includes a display region 10 having a length L₁ and a width T₁, (which may be referred to as width of the display region) and a marginal portion 20 having a width T₂ thereof (which may refer to a width of the marginal portion in the same direction). The marginal portion 20 may be or may include a bezel or bezel portion. If the mobile communication device 1 has a rectangular shape as shown in FIG. 1, although not limited thereto, the width T₁ and the width T₂ may extend in a direction perpendicular to a length or long side of the mobile communication device 1.

The display region 10, having a length L₁ and a width T₁, may refer to an area in which an image may be displayed in the mobile communication device 1, more specifically, a display unit of the mobile communication device 1. The marginal portion 20, having a width T₂, may refer to an area from an edge portion of the housing to an end portion of the display region 10. As the display region 10 increases in size or width, the size of the width T₂ of the marginal portion 20 may decrease in proportion. The width T₂ of the marginal portion 20 may have a minimal or a reference threshold value to secure the stability and the durability of the product.

According to exemplary embodiments of the present invention, the width T₂ of the marginal portion 20 may be decreased while maintaining the stability and the durability of the product. Accordingly, a reduction in size and/or volume of the mobile communication device 1 may be realized while a larger display region 10 may be acquired.

In FIG. 1, a cross-section of X-X′ of the display region 10 and the marginal portion 20 are illustrated on an enlarged scale to provide more detailed view. The mobile communication device 1 according to an exemplary embodiment of the present invention includes a display unit 130, a cover glass 170, and a first housing portion 111, a second housing portion 113, and a third housing portion 115.

The display unit 130 may display an image. The display unit 130 may include various video display devices, such as liquid crystal display (LCD), organic light emitting diode (OLED), and the like may be used. The display unit 130 includes the display region 10 in which an image may be displayed.

The cover glass 170 may be smaller than the size of the display unit 130 and may be larger than the display region 10. The cover glass 170 may be disposed to cover the display unit 130 to protect the display unit 130. The cover glass 170 may be formed by a material that may be transparent and durable. The cover glass 170 may be made of glass, minor-surface glass, or plastic.

Referring to FIG. 1, while a touch sensing unit is illustrated to be built in the display unit 130, the arrangement thereof is not limited thereto. For example, referring to FIG. 2, a touch sensing unit 250 may be separately arranged between the cover glass 270 and the display unit 230 or be attached to the cover glass or the display unit.

More specifically, the touch sensing unit may be provided as one of a type in which the touch sensing unit is separately arranged between the cover glass and the display unit, a type in which the touch sensing unit is attached to the cover glass or the display unit, and a type in which the touch sensing unit is built in the display unit.

According to aspects of the invention, the display unit 130, the cover glass 170, and the touch sensing unit may be combined together as an integrated type. More specifically, the cover glass 170 and the display unit 130 may be bonded together using an optically clear adhesive (OCA) or an optically clear adhesive tape.

The touch sensing unit may be provided as one of the type in which the touch sensing unit is built in the display unit 130, the type in which the touch sensing unit is attached to one face of the cover glass 170 or one face of the display unit 130, and the type in which the touch sensing unit is separately arranged between the cover glass 170 and the display unit 130. Accordingly, the cover glass 170, the display unit 130, and the touch sensing unit may be combined together as an integrated type. However, aspects of the invention are not limited thereto, such that various combinations of the cover glass 170, the display unit 130, and the touch sensing unit may be integrated together without including all three units.

The housing of FIG. 1, which includes the first housing portion 111, the second housing portion 113, and the third housing portion 115, includes a side potion b, which may face a side surface of the display unit 130 and extends in parallel with a direction in which the main body of the mobile communication device 1 extends, and a stopper portion a having a curved portion bending inwards from the side portion b toward a display surface of the side surface of the display unit 130. The stopper portion a may overlap a portion of the display unit 130. More specifically, the stopper portion a may formed or disposed to overlap at least a part of the edge of the display unit 130 that may not be covered by the cover glass 170, such that the display unit 130 may be impeded, obstructed, or prevented from falling out of its place. Since the stopper portion a is included to secure the display unit 130 in its place, the display unit 130 may be restricted or impeded from falling out of its place.

According to exemplary embodiments of the present invention, the housing may be configured as a separation-type housing (see FIG. 1, FIG. 2, and FIG. 4) or an integration-type housing (see FIG. 3).

FIG. 2 illustrates a first housing portion 211, a second housing portion 213, and a third housing portion 215. The second housing portion 213 includes the side portion b facing a side surface of the display unit 230, which may extend in a direction in parallel with a main body of the mobile communication device. The first housing portion 211 may be connected to the second housing portion 213 and includes a stopper portion a. In addition, the second housing portion 213 and the first housing portion 211 may have a separation-type housing structure that may be combined with a third housing portion 215, which may be a rear case of the device, to provide a housing for the mobile communication device. However, aspects of the invention are not limited thereto, such that the housing of the mobile communication device may be a single integrated structure that may not be separable.

Referring to FIG. 3, the structure of the housing may employ an integration-type housing structure in which a side portion b and the stopper portion a are arranged in a single housing structure 311. The integration-type housing 311 may be manufactured using a method in which a metal or plastic material may be injected to form an integration-type structure, but the manufacturing method thereof is not limited thereto.

A housing 311 of FIG. 3 illustrate a support portion and may further include the side portion b to reinforce the strength of the side portion b of the housing. Although not shown in FIG. 3, support portion may reinforce the mechanical strength of the side portion by being installed to the integration-type housing or the separation-type housing. While the support portion may be formed to reinforce the strength of the side portion using metal or a material having strength similar thereto, the material is not limited thereto.

With respect to FIG. 1 and FIG. 2, the support portion 117 and support portion 217 are disposed to reinforce the mechanical strength of the side portion of the first housing portion 111 and the first housing portion 211, respectively. Further, the support portion 117 and support portion 217 are illustrated to be combined with the first housing portion 111 and the first housing portion 211, respectively, to form the separation-type housing. Each of or some of the support portions or housing portions may be formed using an insert injection method, however, aspects of the invention are not limited thereto.

According to an exemplary embodiment of the present invention, the housing may be formed using a metal material or a plastic material. When a separation-type housing is formed of several housing portions or components, a structure may be formed or put together using a metal material and/or a plastic material. For an integration-type housing, a housing that may be integrally formed using a metal material or a plastic material may be provided. For a housing formed using a plastic material, the housing may be processed in an easier manner. Further, for a housing formed using a metal material, the strength of the housing may be superior, and a housing having predetermined strength may be realized without arranging an additional support portion.

As illustrated in FIG. 1, the first housing portion 111 adjacent to the display region 10 includes the stopper portion a that supports at least a part of the edge of the display unit 130 to prevent or impede the display unit 130 from being dropped out and may decrease the width T₂ of the marginal portion 20.

The first housing portion 111 includes the side portion b that may be thicker than the display unit and extend in a direction parallel with a direction in which the display unit extends. The first housing portion 111 also includes the stopper portion a, which has a shape bending in a direction from the side portion b toward the display unit 130. The stopper portion a may overlap at least a part of the edge of the display unit 130 that may not be covered by the cover glass 170. Accordingly, the first housing portion 111 may support the display unit 130 and may reduce a likelihood of occurrence of a crack in the display unit 130 by restraining the display unit 130 from being dropped out by passing over the stopper portion a.

According to an exemplary embodiment of the present invention, a foreign material blocking part 190 may be arranged between the stopper portion a and the display unit 130. The foreign material blocking part 190 may block or impede an inflow of a foreign material or water into the inside of the device by impeding or blocking a foreign material from flowing in between the stopper portion a and the display unit 130 from the outside. The foreign material blocking part 190 may be formed using an elastic material or sponge that may serve as a cushion, which may alleviate or reduce a shock that may occur between the stopper portion a and the display unit 130. The foreign material blocking part 190 may be formed by using one or more materials selected from a group including a synthetic resin, rubber, silicone, liquid silicone rubber (LSR), and the like, but the material is not limited thereto.

The mobile communication device 1 having the structure according to an exemplary embodiment of the present invention may have a smaller width T₂ of the marginal portion 20.

For example, as shown in FIG. 1, when the size of the width T₁ is A, the size of the display unit 130 is B, the size of the cover glass 170 is C, and the width of the second housing 111 is D, the width T₂ may be ½ (D−A), which corresponds to a sum of y₁ (½(B−A)) and y₂ (½(D−B)).

More specifically, the width T₂ of the marginal portion 20 may be determined based on a distance from the display unit 130 to an end portion of the display region 10, which may be y₁, and a distance from the outer face of the first housing 111 to the display unit 130, which may be y₂ and correspond to the thickness of the housing.

More specifically, when the distance from the display unit 130 to the end portion of the display region 10 is denoted by y₁, the thickness of the housing may be denoted by y₂, and a gap between the display unit 130 and the housing may be denoted by α, the width T₂ of the marginal portion can be represented as the following Equation 1.

T₂=y₁+y₂+α Equation 1

Here, α may refer to a gap between the display unit 130 and the housing, and FIG. 1 may represent an exemplary embodiment in which α is smaller than y₁ and y₂ and has a value that is close to zero.

Further, at least one of the thickness of an area used for attaching and fixing the touch sensor or the cover glass, and a distance corresponding to the thickness of the housing, the width T₂ of the marginal portion 20 may be determined based on the distance y₁, which may be a distance from the end portion of the display region 10 to the display unit 130, and the thickness y₂, which may be a thickness of the second housing 111.

More specifically, in the related art, while the area used for attaching and fixing the touch sensor or the cover glass is necessary to prevent the display module from falling out of its housing, according to an exemplary embodiment of the present invention, the display unit 130 is fixed by the stopper portion a, and accordingly, such an area may not be additionally arranged. Accordingly, the width T₂ of the marginal portion 20 may be less than the marginal portion in the related art by about 1.4 mm.

According to an exemplary embodiment of the present invention, the cover glass 170 may be formed to be smaller than the display unit 130 and larger than the display region 10 or its width T₁. More specifically, where the cover glass is formed to be smaller than the display region 10 or its width T₁, the display region 10 may not be protected in a stable manner, and where the cover glass is formed be larger than the display unit 130, the size of the product may increase.

In the related art, the cover glass 170 is formed to be larger than the display unit 130 to prevent the display unit 130 from being dropped out. However, according to an exemplary embodiment of the present invention, since the display unit 130 is fixed by using the stopper portion a, the cover glass 170 may not need to be formed to be as large, and accordingly, the cover glass 170 may be formed to be smaller than the display unit 130 and larger than the display region 10 or its width T₁.

FIG. 2 is a partial enlarged view of a mobile communication device according to an exemplary embodiment of the present invention. Referring to FIG. 2, a touch sensing unit 250 is separately arranged between a cover glass 270 and a display unit 230.

Referring to FIG. 2, the touch sensing unit 250 is disposed between the cover glass 270 and the display unit 230. An integration-type structure may be formed in which the cover glass 270, the touch sensing unit 250, and the display unit 230 are sequentially stacked.

Similar to the exemplary embodiment of FIG. 1, a first housing 211, a second housing 213, and a third housing 214 are formed to have a structure, which includes a stopper portion a. Further, a foreign material blocking part 290 is disposed between the stopper portion a and the display unit 230. The foreign material blocking part 290 may be formed using a material that has superior sealing capability and may impede or block penetration of moisture or a foreign material between the display unit 230 and the housings. Furthermore, the foreign material blocking part 290 may be formed using a material that has elasticity, such that an occurrence of a crack in the display unit 230 due to friction between the display unit 230 and the housings may be reduced or prevented.

Also, similar to the exemplary embodiment of FIG. 1, the stopper portion a is included. Further, an additional bonding and fixing area that may be used for fixing the display unit 230 may not be used. Therefore, the width T₂′ of a marginal portion may increase in proportion to a distance from an end portion of the display unit 230 to a display region having a width T₁′ and at least one of the thicknesses of the first housing 211, the second housing 213, and the third housing 215 may be reduced.

According to aspects of the invention, a separation-type housing structure that may include at least one of the first housing 211, the second housing 213, and the third housing 215. The at least one of the first housing 211, the second housing 213, and the third housing 215 may be formed from plastic. However, aspects of the invention are not limited thereto, such that other materials may be used. Further, to reinforce the strength of the housings in consideration of the characteristics of the plastic or other material, a support portion 217 may be further included, which is attached to a side portion b of the housing or is insert-injected together with the second housing 211.

FIG. 3 is a partial enlarged view of a mobile communication device according to an exemplary embodiment of the present invention. More specifically, FIG. 3 illustrates a housing 311 that has an integration-type structure.

According to an exemplary embodiment of the present invention, the housing 311 may be configured as an integration-type housing. The housing 311 may be formed using a metal material, such as stainless steel, but the material is not limited thereto.

The housing 311 includes a stopper portion a that may protrude or extend toward a display region having a width T₁″, and a side portion b arranged in parallel with respect to an elongated side or portion of a display unit 330.

If the housing 311 is formed using a metal material, predetermined strength may be secured, and accordingly, a desired level of strength may be secured without arranging an additional metal support portion. According to an exemplary embodiment of the present invention, a housing formed using a metal material, since the metal support portion is not included, the thickness of a portion out of the width T₂” of the whole marginal portion that corresponds to the thickness of the housing 311 may decrease or be reduced, and the width T₂″ of the marginal portion may be decreased or reduced by about 0.8 mm to about 1.2 mm.

More specifically, by using the housing formed of a metal material, the thickness of the side portion b may decrease, and the width T₂″of the marginal portion may also decrease.

Referring to FIG. 3, a foreign material blocking part 390 is arranged between the display unit 330 and a stopper portion a of the housing 311. The housing 311 may be formed using a metal material, and the foreign material blocking part 390 may be formed using an elastic material. Accordingly, the occurrence of a crack in the stopper portion a, which may be formed using a metal material, and the display unit 330 due to a collision therebetween may be reduced or prevented.

In addition, the display unit 330 of a touch sensing unit, which may be a built-in-type, may be provided. Here, the display unit 330 and the cover glass 370 may be integrally provided as an integration type, and the assembly process may be performed in a simple manner, such as by inserting the integration-type structure (i.e., structure including the display unit 330 and the cover glass 370) into the housing 311.

FIG. 4 is a partial enlarged view of a mobile communication device according to an exemplary embodiment of the present invention. For example, the structure of the mobile communication device includes a housing formed by using a metal material.

According to an exemplary embodiment of the present invention, the housing 411 may be configured as a separation-type housing that includes a housing formed using a metal material. An upper housing 411 may be formed by using, without limitation, a metal material, such as stainless steel. A lower housing 419 may be formed by using at least one of a metal material, a plastic material, or the like, but the materials are not limited thereto.

In order to reduce a likelihood of incurring damage due to a friction between the housing 411, which may be formed using a metal material, and a display unit 430, a foreign material blocking part 491 may be arranged between the housing 411 and the display unit 430.

According to an exemplary embodiment of the present invention, the foreign material blocking part 491 may be formed to have a height that is equal to or larger than a gap between the inner or interior face of the housing 411 and the display unit 430. The foreign material blocking part 491 may have a height that is equal to or smaller than a gap between the outer face of the housing 411 and the display unit 430. More specifically, the upper face of the foreign material blocking part 491, the upper face of the cover glass 470, and the upper face of the housing 411 may be formed to be arranged on one straight line.

In addition, the foreign material blocking part 491 may have a width larger than the gap between the cover glass 470 and the housing 411 and extend towards the inner face of the housing 411 while filling the gap between cover glass 470 and the housing 411.

According to an exemplary embodiment of the present invention, the foreign material blocking part 491 may have a width in the range of 0.05 mm to 0.15 mm and a height in the range of 0.1 mm to 0.2 mm. For example, the foreign material blocking part 491 may have a width of about 0.1 mm and a height of about 0.12 mm, but the width and the height are not limited thereto.

Further, the foreign material blocking part 491 may be a cushion between the display unit 430 and the housing 411. The foreign material blocking part 491 may alleviate or reduce a shock that may be applied due to friction between the display unit 430 and the housing 411, thereby reducing a likelihood of the display unit 430 being damaged. In addition, the foreign material blocking part 491 may block or reduce the penetration of at least one of a foreign material, moisture, or liquid into the gap between the display unit 430 and the housing 411.

According to an exemplary embodiment of the present invention, the foreign material blocking part 491 may be formed using, without limitation, at least one of an elastic material, such as sponge, and one or more selected from a group including rubber, silicon, a synthetic resin, a liquid silicone rubber (LSR), and the like.

According to an exemplary embodiment of the present invention, the foreign material blocking part 491 may be formed or disposed to be fixed at one end of a support frame 493. Referring to FIG. 4, the foreign material blocking part 491 may surround one end of the support frame 493 and be fixed to the support frame 493. More specifically, the support frame 493 may be formed or disposed such that the foreign material blocking part 491 may be attached and fixed to one end thereof, and the other end extends along the inner face of the housing 411.

While the foreign material blocking part 491 may be fixed at a desired position between the display unit 430 and the housing 411, the foreign material blocking part 491 may be integrally provided by being insert-injected to one end of the support frame 493 for easier assembly process.

According to an exemplary embodiment of the present invention, the other end of the support frame 493 may extend along the inner face of the housing 411 and be fixed by being in contact with the inner face of the housing 411. Referring again to FIG. 4, although the support frame 493 is illustrated as extending to a stopper portion a and an inner face of a part of the housing 411, aspects of the invention are not limed thereto such that any form may be employed. The support frame 493 may extend along the inner face of the housing 411 and may have an “L” shape extending toward the display unit.

Accordingly, by arranging the support frame 493 having the foreign material blocking part 491 attached to one end thereof between the housing 411 and the display unit 430, the foreign material blocking part 491 may be fixed at a target position.

According to an exemplary embodiment of the present invention, in the display unit 430, a shock buffering unit 417 may be additionally arranged between the display unit 430 and a support structure 413 that may be used for supporting the display unit 430 inside the device. The shock buffering unit 417 may be used for alleviating a shock that may occur between the display unit 430 and the support structure 413. The display unit 430 and the support structure 413 may be configured as being separate from each other by a predetermined gap to arrange the shock buffering unit 417 therebetween and may be configured to be separate from each other by about 0.2 mm, but the configuration thereof is not limited thereto. By arranging the shock buffering unit 417, a mobile communication device having improved shock durability may be provided.

In order to allow the housing 411 to have a target strength and support the display unit 430, the stopper portion a may have a thickness of 0.3 mm or more, but the thickness is not limited thereto. In addition, if the housing 411 is formed using a metal material, the housing may be manufactured such that the side portion b has an approximate thickness of about 1.0 mm, for example, a thickness of 1.05 mm, but the thickness is not limited thereto such that the housing may be manufactured to have any thickness based on the design or the material of the product.

While the housing 411 formed using a metal material may not be easily broken due to its higher strength, the housing 411 may be deformed in the shape in accordance with external pressure or a shock that may be applied thereto. Accordingly, to reduce a likelihood of such deformation in shape of the housing 411, the housing 411 may be formed to be combined with an internal structure to disperse the applied shock or pressure.

More specifically, the housing 411 formed using a metal material may be combined with and fixed to a support structure 413 that may be arranged to support the display unit 430 inside the mobile communication device by being screwed thereto or being fitted therein.

Where the support structure 413 is screwed to the housing 411, when the support structure 413 or the display unit 430 moves in response to receiving pressure or a shock, the housing 411 may become worn or damaged by a sheering breaking force of screws. Therefore, to reduce a likelihood of such wear or damage, a guide member 415 may be additionally arranged between the housing 411 and the support structure 413.

The guide member 415 may be combined with the support structure 413 and be fixed to the housing 411. More specifically, a screw hole H may extend in the support structure 413 and the guide member 415 such that the support structure 413 and the guide member 415 may be combined together by being screwed to each other. Accordingly, while the support structure 413 and the housing 411 formed using a metal material may be fixed in a stable manner, the housing 411 may be less likely from being damaged due to a sheering breaking force of the screws that may be applied to the support structure 413 or the display unit 430.

In the related art, there is inconvenience in that the display module is inserted and an additional process of bonding or fixing the cover glass is necessary, or the display module and s the cover glass need to be separately inserted into partitioned spaces. However, according to exemplary embodiments of the present invention, while the display module and the cover glass may be assembled in a simpler manner, a method for manufacturing a mobile communication device that may secure a wide display region may be provided.

As illustrated in FIG. 1, a method for manufacturing a mobile communication device according to an exemplary embodiment of the present invention includes an operation of preparing a display unit 130. The display unit 130 may include a display region 10 for displaying a video, a cover glass 170 to cover the display unit 130, in which the cover glass 170 may be smaller than the display unit 130 and larger than the display region, and a touch sensing unit that may be arranged in the display unit 130 or the cover glass 170. The method may also include an operation of mounting the display unit 130, the cover glass 170, and the touch sensing unit on at least one of a first housing 111, a second housing 113, and a third housing 115 that include a stopper portion a that may support edges of the display unit 130 to impede or block the display unit 130 from being dropped out and decrease the width T₂ of the marginal portion.

More specifically, the display unit 130, the cover glass 170, and the touch sensing unit may be prepared.

The display unit 130 may display an image, and, according to exemplary embodiments of the present invention, various video display devices, such as liquid crystal displays may be used. The display unit 130 may include the display region 10 in which an image is displayed.

The cover glass 170 may be formed to cover the display unit 130 for protecting the display unit 130 and, and the width of the cover glass 170 may be smaller than the size of the display unit 130 and larger than the display region.

The touch sensing unit may be used for sensing a user's touch. According to an exemplary embodiment of the present invention, the touch sensing unit may be provided as one of the type in which the touch sensing unit may be built in the display unit 130, the type in which the touch sensing unit is attached to one face of the cover glass 170 or one face of the display unit 130, and the type in which the touch sensing unit is separately arranged between the cover glass 170 and the display unit 130. Accordingly, the cover glass 170, the display unit 130, and the touch sensing unit may be combined together as an integrated type. According to exemplary embodiments of the present invention, the touch sensing unit may be formed to be smaller than the size of the cover glass 170.

After the cover glass 170, the display unit 130, and the touch sensing unit are prepared, an operation of mounting the cover glass 170, the display unit 130, and the touch sensing unit on the housing is included.

The first housing 111, the second housing 113, and the third housing 115 according to an exemplary embodiment of the present invention, more specifically, the second housing 111, which may be disposed adjacent to the display region 10, may include a stopper portion a that may overlap the edge of the display unit 130 to impede or block the display unit 130 from being dropped out and decrease the width T₂ of the marginal portion 20. The stopper portion a may support a part or the whole of the edge of the display unit 130 that may not be covered with the cover glass 170.

The second housing 111 may include a side portion b that may face the side face of the display unit 130 in parallel therewith, and the stopper portion a may have a shape bending in a direction from the side portion b toward the display unit 130.

Accordingly, by mounting the display unit 130, the cover glass 170, and the touch sensing unit on a structure including the first housing 111, the second housing 113, and the third housing 115 in which the stopper portion a is disposed, the stopper portion a may impede or block the display unit 130 from being dropped out, whereby formation of a crack in the display unit 130 may be impeded or blocked.

According to an exemplary embodiment of the present invention, the housing may be configured as a separation-type housing (see FIG. 1, FIG. 2, and FIG. 4) or an integration-type housing (see FIG. 3).

Similar to the exemplary embodiments illustrated in FIG. 1 and FIG. 2, a structure including at least one of a first housing, a second housing, and a third housing may include a side portion b, which may be included in the first housing and faces a side face of a display unit in parallel therewith. Further, the second housing may be connected to the first housing and may include the stopper portion a. In addition, the first housing and the second housing may have a separation-type housing structure that configures a mobile communication device housing, in which the third housing configures a rear case of the device.

However, aspects of the invention are not limited thereto, such that the structure of the housing may be an integration-type housing structure in which a side portion and a stopper portion may be arranged in one housing. The integration-type housing may be manufactured using a method in which a metal or plastic material is injected to form an integration-type structure, but the manufacturing method thereof is not limited thereto.

According to exemplary embodiments of the present invention, a support portion may be further included on the side portion to reinforce the strength of the side portion of the housing. According to exemplary embodiments of the present invention, the housing may be formed using a metal material or a plastic material.

According to an exemplary embodiment of the present invention, since the display unit 130, the cover glass 170, and the touch sensing unit are mounted through one mounting process, the manufacturing process may be simplified. In addition, since the housing having the structure of the stopper portion a may be used, a method of manufacturing a mobile communication device may be provided, which may reduce the width T₂ of the marginal portion 20 while securing an area of the display region 10.

According to an exemplary embodiment of the present invention, an operation of arranging a foreign material blocking part 190 between the stopper portion a and the display unit 130 may be further included. After the foreign material blocking part 190 is inserted into or attached to the housing 111, the display unit 130 and the cover glass 170 may be mounted, or the arrangement may be performed using a method in which, after the display unit 130 and the cover glass 170 are mounted on the housing 111, the foreign material blocking part 190 may be inserted into a space formed therebetween.

In addition, according to an exemplary embodiment of the present invention, the foreign material blocking part 491 (see FIG. 4) may be provided in the state of being injected integrally with the support frame 493. Accordingly, the foreign material blocking part 491 may be fixed at a target position in the assembly process.

The foreign material blocking part 190 may impede or block an inflow of a foreign material into a space between the stopper portion a and the display unit 130 and may be formed using an elastic material that may serve as a cushion by alleviating a shock that may occur between the stopper portion a and the display unit 130. The foreign material blocking part 190 may be formed by using a sponge material or an elastic material, but the material is not limited thereto.

According to technology in related art, the width of the marginal portion needs to be in the range of a minimum of 4.6 mm to 6.1 mm, and where a marginal portion of which the size is less than 4.0 mm is formed there are problems in the durability and the like. However, according to exemplary embodiments of the present invention, the width of the marginal portion may be decreased to have a range of 2.5 mm to 3.5 mm and furthermore up to 2.75 mm to 3.0 mm. Further, where the width of the marginal portion is decreased, problems such as formation of a crack in the display unit and a decrease in the strength may be less likely or may not occur.

Furthermore, a difference between the width T₂ of the marginal portion, which may be an area from the end portion of the display region 10 to the exterior of the side portion of the housing, and the thickness y₂ of the housing may be decreased up to 1.5 mm to 3.0 mm. According to exemplary embodiments of the present invention, the thickness of the housing may differ in the marginal portion 20 in the aspect of the design, and the width T₂ of the marginal portion 20 may be decreased in an effective manner in consideration of the structural aspect of the mobile communication device.

Therefore, a mobile communication device and a manufacturing method thereof according to exemplary embodiments of the present invention may allow the size of the product to be reduced while allowing the size of the display region to increase. Further, the reliability and the stability of the product may be more secured. In addition, the mobile communication device may be more easily gripped by a user's hand.

Furthermore, by providing a housing that has a bent shape (e.g., a stopper portion), the strength of the housing may be reinforced, and the display unit may be more stably fixed to the housing while the size of the marginal portion may be decreased. Further, likelihood in the formation of a crack in the display unit may be reduced or prevented, whereby the reliability and the stability of the product may be more secured.

Although exemplary embodiments of the present invention have been described with respect to a mobile communication device, aspects of the invention are not limited thereto, such that a mobile device or terminal, a stationary device or terminal, a display device or terminal, and the like may incorporate features of the invention.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A device, comprising:
a display unit;
a cover glass to at least partially overlap the display unit; and
a housing unit comprising a stopper portion, the stopper portion extending to overlap a portion of the display unit, and the stopper portion being adjacent to the cover glass.

2. The device of claim 1, wherein the display unit is adhered to the cover glass.

3. The device of claim 1, wherein the housing unit comprises a plurality of housing portions.

4. The device of claim 1, wherein the housing unit is an integrated unit.

5. The device of claim 1, further comprising:
a touch sensing unit disposed between the cover glass and the display unit.

6. The device of claim 1, wherein the stopper portion has a curved portion extending from a side portion of the housing unit towards a surface of the display unit.

7. The device of claim 1, wherein the cover glass overlaps a first portion of the display unit and the stopper portion overlaps a second portion of the display unit.

8. The device of claim 1, further comprising:
a foreign material blocking part to impede inflow of foreign material into the device.

9. The device of claim 8, wherein the foreign material blocking part is disposed between the stopper portion and the display unit.

10. The device of claim 8, wherein the foreign material blocking part is disposed between the housing unit and the display unit.

11. The device of claim 8, wherein the foreign material blocking part has a height equal to or greater than a gap between an interior surface of the housing unit and an edge of the display unit.

12. The device of claim 8, wherein the foreign material blocking part fills a gap between the cover glass and the housing unit.

13. The device of claim 8, further comprising:
a support frame,
wherein a first end of the support frame is attached to the foreign material blocking part and a second end of the support frame is attached to an interior surface of the housing unit.

14. The device of claim 1, further comprising:
a support structure attached to the housing unit;
a guide member disposed between the housing unit and the support unit; and
a shock buffering unit disposed between the display unit and a support structure.

15. A device, comprising:
a display unit;
a cover glass to overlap a first portion of the display unit, the first portion being less than an entire portion of the display unit; and
a housing unit comprising a stopper portion, the stopper portion to overlap a second portion of the display unit.

16. The device of claim 15, wherein the stopper portion has a portion extending from a side portion of the housing unit towards a surface of the display unit.

17. The device of claim 15, further comprising:
a foreign material blocking part disposed between the stopper portion and the display unit.

18. The device of claim 17, further comprising:
a support frame,
wherein a first end of the support frame is attached to the foreign material blocking part and a second end of the support frame is attached to an interior surface of the housing unit.

19. The device of claim 15, further comprising:
a support structure attached to the housing unit;
a guide member disposed between the housing unit and the support unit; and
a shock buffering unit disposed between the display unit and a support structure.

20. A method for manufacturing a device, comprising:
preparing a display unit; and
mounting the display unit and a cover glass to a housing unit comprising a stopper portion,
wherein the cover glass at least partially overlaps the display unit, and the stopper portion extends to overlap a portion of the display unit.
